(19) United States
(12) Patent Application Publication
(10) Pub. No.: US 2015/0187957 A1
(43) Pub. Date: Jul. 2, 2015

(54) TRANSISTOR WITH IMPROVED RADIATION HARDNESS

(71) Applicant: Texas Instruments Incorporated, Dallas, TX (US)

(72) Inventors: Hao DING, Richardson, TX (US); Seetharaman SRIDHAR, Richardson, TX (US)

(21) Appl. No.: 14/584,369

(22) Filed: Dec. 29, 2014

Related U.S. Application Data
(60) Provisional application No. 61/922,414, filed on Dec. 31, 2013.

(51) Int. Cl. H01L 29/786; H01L 29/66; H01L 27/088

(52) U.S. Cl. CPC H01L 29/78612; H01L 29/78618; H01L 27/088; H01L 29/66477

(57) ABSTRACT

An integrated circuit and method with a radiation hard transistor where the gate of the radiation hard transistor does not cross the boundary between active and isolation.

### CROSS-REFERENCE TO RELATED APPLICATIONS

This application claims the benefit of priority under U.S.C. §119(e) of U.S. Provisional Application 61/922,414 (Texas Instruments docket number TI-71788, filed Dec. 31, 2013), the contents of which are hereby incorporated by reference.

### FIELD OF INVENTION

This invention relates to the field of integrated circuits. More particularly, this invention relates to radiation hardened transistors in integrated circuits.

### BACKGROUND

Radiation hardened integrated circuits are required for integrated circuits used in satellites and other equipment used in space and also required for certain military applications.

Conventional non radiation hard NMOS transistors are shown in a top down view in FIG. 1A and FIG. 1B and in the cross section in FIG. 1C. The NMOS transistors in FIGS. 1A and 1B consist of active area 114 and transistor gate 108. In FIG. 1A the channel of the NMOS transistor is formed between source 104 and drain 102. In FIG. 1B a first NMOS transistor channel is formed between source 106 and common drain 104. A second MOS transistor channel is formed between source 102 and common drain 104.

A cross sectional view taken parallel through the transistor gate along cut line 112 in FIG. 1A or FIG. 1B is shown in FIG. 1C. The transistor gate 108 covers the bird's beak boundary 110 between LOCOS isolation 118 and the transistor gate dielectric 120.

Parasitic transistor channels may form in parallel with the NMOS transistor channel under the bird's beak isolation of the LOCOS isolation 118. Because the LOCOS oxide which forms the gate dielectric of the parasitic birds beak transistors is thicker than the transistor gate dielectric 120 the turn on voltage (Vtn) of the parasitic birds beak transistor is higher than the Vtn of the core transistor. Normally these parasitic birds' beak transistors do not turn on. In environments with high levels or radiation such as outer space, the radiation may generate charge in the LOCOS gate dielectric that lowers the Vtn of the parasitic bird's beak transistor resulting in increased leakage current when the NMOS transistor is turned off. This increased leakage current may cause logic states in the integrated circuit to lose charge resulting in circuit failure.

As shown in FIG. 2, prior to radiation the off current (Ioff) of the transistors shown in FIG. 1A is below 1 micro amp (graph 202). After 100 k units of radiation, the leakage current is increased approximately two orders of magnitude (graph 206). As shown in FIG. 1C the radiation causes positive charge 124 to accumulate in the bird's beak region 110. This accumulated positive charge 124 lowers the Vtn of the parasitic bird's beak transistor resulting in an increase in Ioff.

### SUMMARY

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

An integrated circuit and method with a radiation hard transistor where the gate of the radiation hard transistor does not cross the boundary between active and isolation.

### BRIEF DESCRIPTION OF THE DRAWINGS

FIG. 1A-1C (Prior art) are top down views and a cross-section of conventional radiation hard transistors.

FIG. 2 is a graph of the leakage current of a conventional radiation hard transistor pre and post radiation.

FIG. 3A-3C are top down views and a cross-section of embodiment radiation hard transistors formed according to principles of the invention.

FIG. 4 is a graph of the leakage current of an embodiment radiation hard transistor pre and post radiation.

FIG. 5A-5B are cross sections of an embodiment high voltage radiation hard transistor formed according to principles of the invention.

FIGS. 6A and 6B are a top down views of embodiment radiation hard transistors formed according to principles of the invention.

FIGS. 7A-7I are cross sections of steps in the fabrication of integrated circuits formed according to principles of the invention.

FIGS. 8A-8I are cross sections of steps in the fabrication of integrated circuits formed according to principles of the invention.

FIGS. 9A-9B are plan views of steps in the fabrication of integrated circuits formed according to principles of the invention.

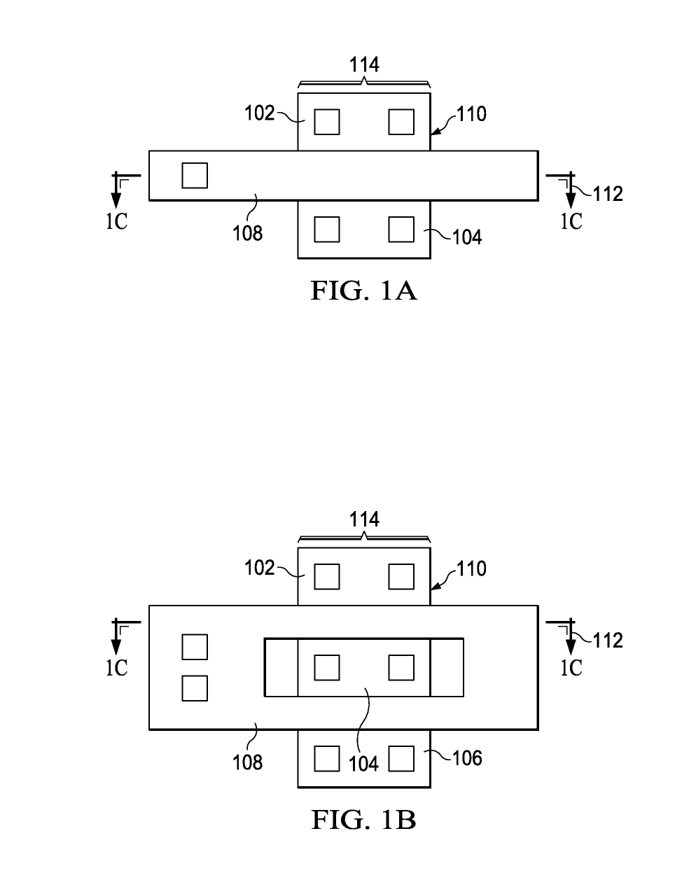

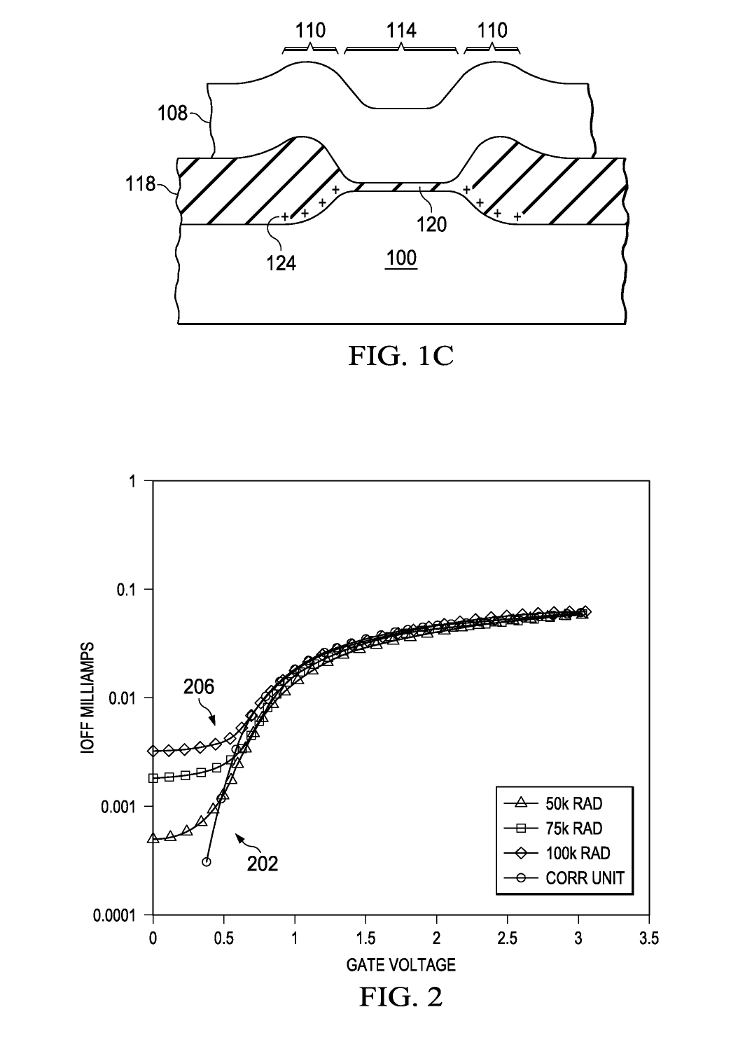

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

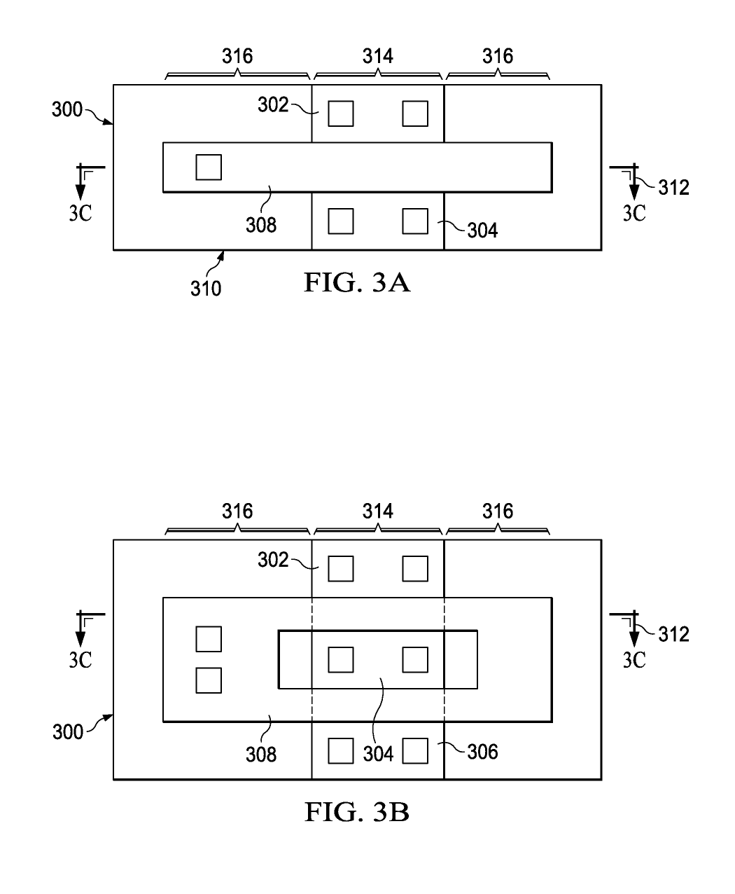

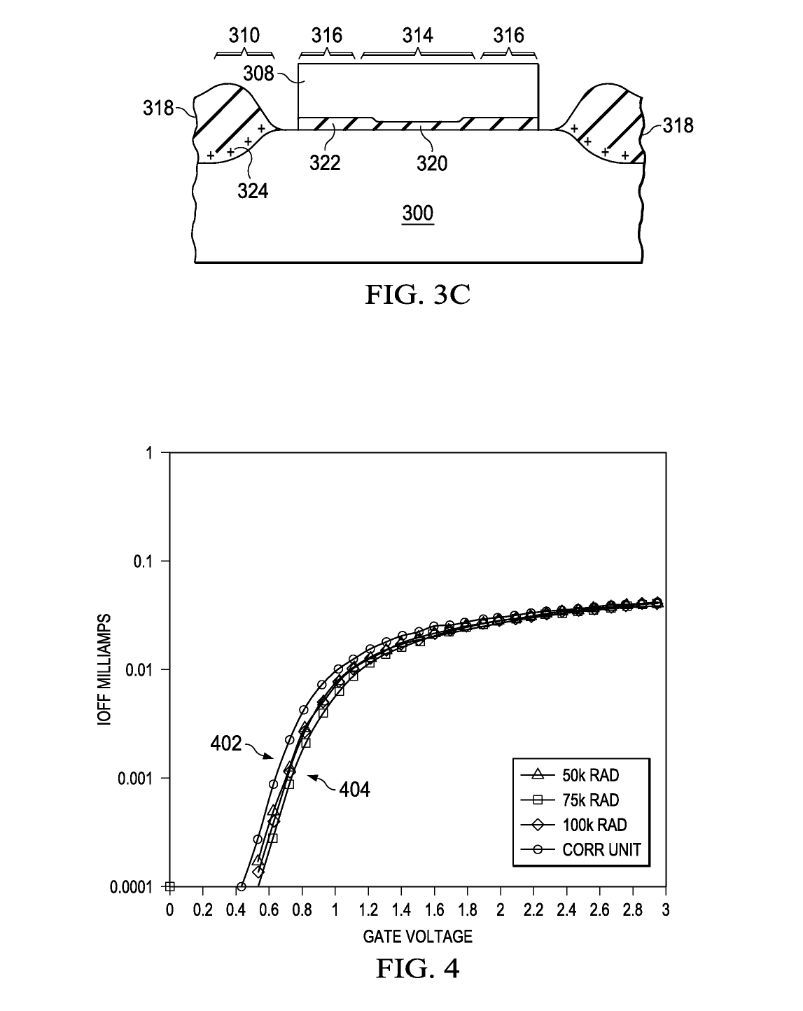

Embodiment n-channel metal-oxide-semiconductor (NMOS) transistors with improved radiation hardness are shown in top down view in FIGS. 3A and 3B and in cross sectional view in FIG. 3C.

In FIG. 3A the channel of the embodiment radiation hard transistor channel is formed in the active 314 region under the gate 308 between the source 302 and drain 304 diffusions. The transistor gate 308 is completely contained within the active area 300. When the source 302 and drain 304 of embodiment radiation hard transistor are silicided, the silicide is blocked from the pn-junction formed at the boundary between source and drain, 302 and 304, diffusions and the active 300. This prevents the source 302 and drain 304 diodes from shorting to the substrate 300.

An embodiment dual gate radiation hard transistor is illustrated in FIG. 3B. The channel of a first embodiment rad hard NMOS transistor is formed under the dual gate 308 in the active 314 between a first source 302 and common drain 304. The channel of a second embodiment rad hard NMOS transistor is formed under the dual gate 308 between a second source 306 and common drain 304. The gate 308 of the embodiment rad hard transistor is surrounded by active 300 and does not cross the active/isolation boundary.

As is illustrated in FIG. 3C, the embodiment radiation hard dual transistor is fully contained within the active 300. The gate 308 of the embodiment radiation hard dual transistor does not cross the bird's beak 310. The increased leakage current caused by accumulation of positive charge in the birds beak is thus avoided since the birds beak 310 in the embodiment rad hard transistor is not under the gate 308 and no parasitic transistor is formed.

As shown in FIG. 3C, the transistor channel regions 314 are formed over a thin transistor gate dielectric 320. An optional thicker gate dielectric 322 may be formed under the transistor gate 308 that is over the active regions 316 outside the channel region 314. The thicker gate dielectric 322 may reduce transistor capacitance and improve transistor performance.

Since the bird's beak 310 is not under the transistor gate 308 in the embodiment rad hard NMOS transistors, no parasitic bird's beak transistor is formed and an increase in Ioff during radiation is thus avoided.

As shown in FIG. 4, the leakage current of the embodiment rad hard transistor in FIG. 3A remains below 1 micro amp 404 even after exposure to 100 k units of radiation. The positive charge 324 (FIG. 3C) that accumulates in the isolation oxide 318 in birds beak area 310 does cause increased off current in the embodiment rad hard transistor.

The thickness of the transistor gate dielectric 320 depends upon the voltage the transistor is required to switch. For a 3.3 volt transistor the gate dielectric 320 may have a thickness in the range of 78 nm to 88 nm. In an example embodiment 3.3 volt rad hard transistor the gate dielectric 320 is about 83 nm of silicon dioxide.

The thickness of higher voltage gate dielectric 322 under the gate 308 outside the channel region may be at least 2 times the thickness of the transistor gate dielectric 320 and preferably at least 4 times the thickness. In an example embodiment 3.3 volt rad hard transistor the gate dielectric 320 is about 83 nm of silicon dioxide and the higher voltage gate dielectric 322 is about 200 nm of silicon dioxide.

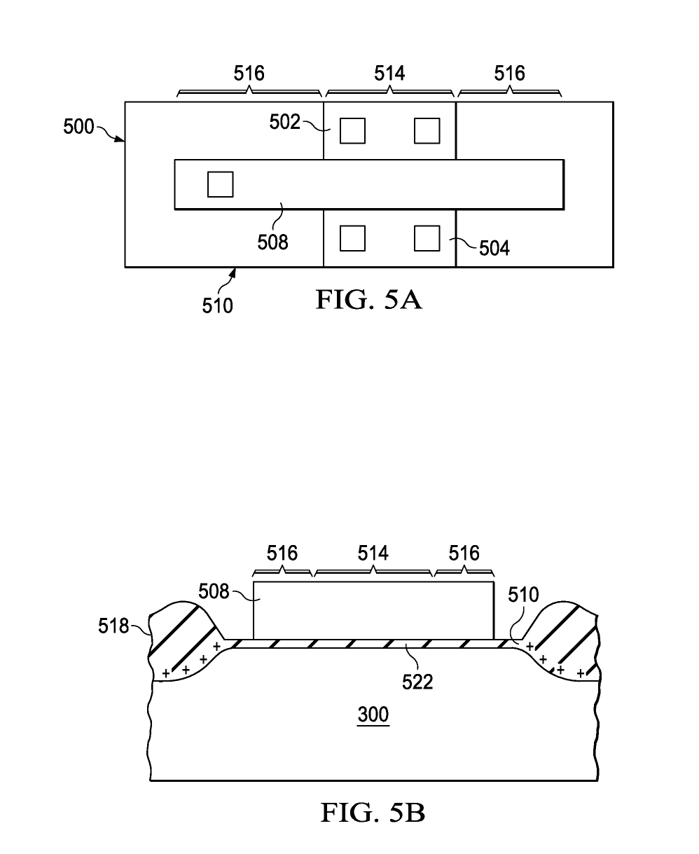

An embodiment high voltage radiation hard transistor is illustrated in the top down view in FIG. 5A and a cross sectional view in FIG. 5B. The channel of the embodiment high voltage radiation hard transistor lies under the gate 508 between the source 502 and the drain 504 regions. The high voltage radiation hard transistor gate 508 is surrounded by active 500 and does not cross the bird's beak 510 which borders the active area 500. In the embodiment high voltage radiation hard transistor the channel region 514 is formed under the high voltage gate dielectric 522 and in this embodiment the non-channel regions 516 may also be formed under high voltage gate dielectric. When the source and drain, 502 and 504, are silicided, silicide formation is blocked from the boundaries between the source and drains 502 and 504, and the substrate 500 so that the source and drain diodes are not shorted to substrate 500.

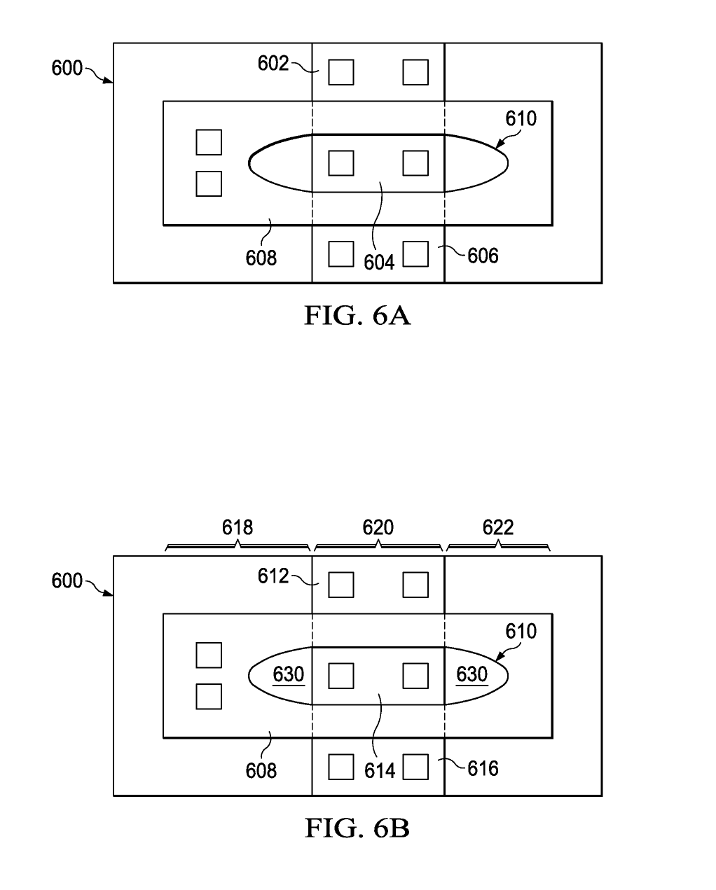

Another embodiment of a dual gate radiation hard transistor is shown in FIG. 6A. In this embodiment the inside corners 610 of the opening in the gate 608 in which the common drain 604 is formed are rounded to eliminate sharp corners where electric field may be enhanced. Rounding the corners 610 of the opening in the gate 608 that surrounds the common drain 604, reduces the electric field and may reduce gated diode leakage. The area of the drain 604 is increased.

As shown in FIG. 6B silicide formation may be blocked from active regions 630 where the area of the drain 604 is increased. Blocking the silicide from these areas increases the surface resistance to current flow through these areas 630 and reduces variation in the drive current of one embodiment dual gate radiation hard transistor to another embodiment dual gate radiation hard transistor in the same IC.

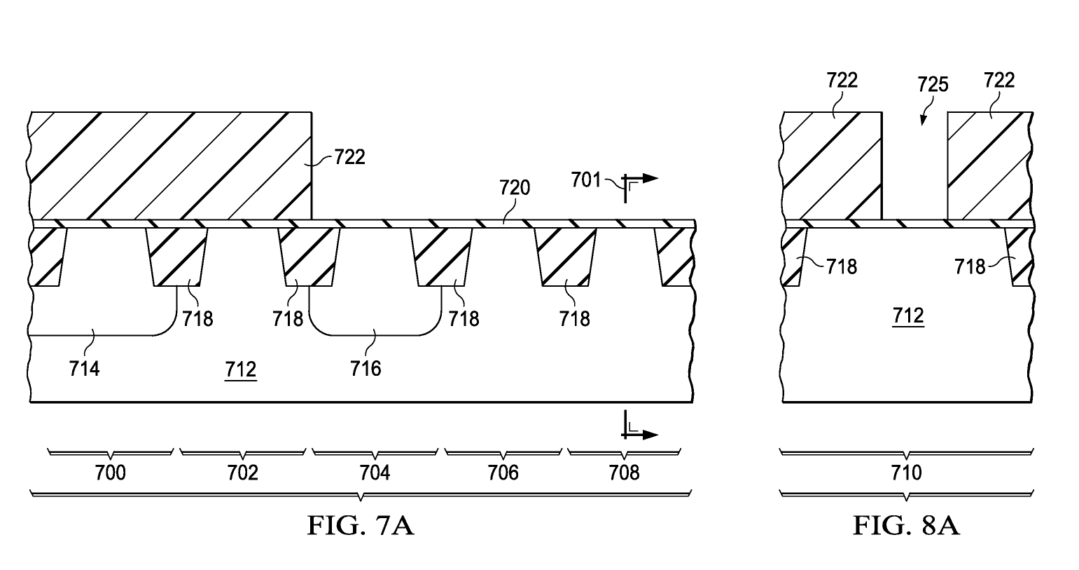

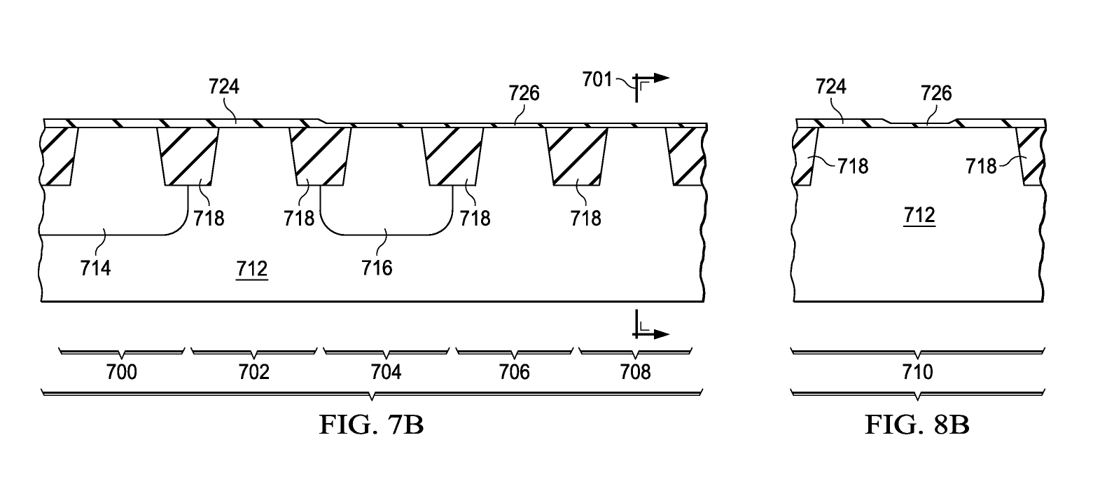

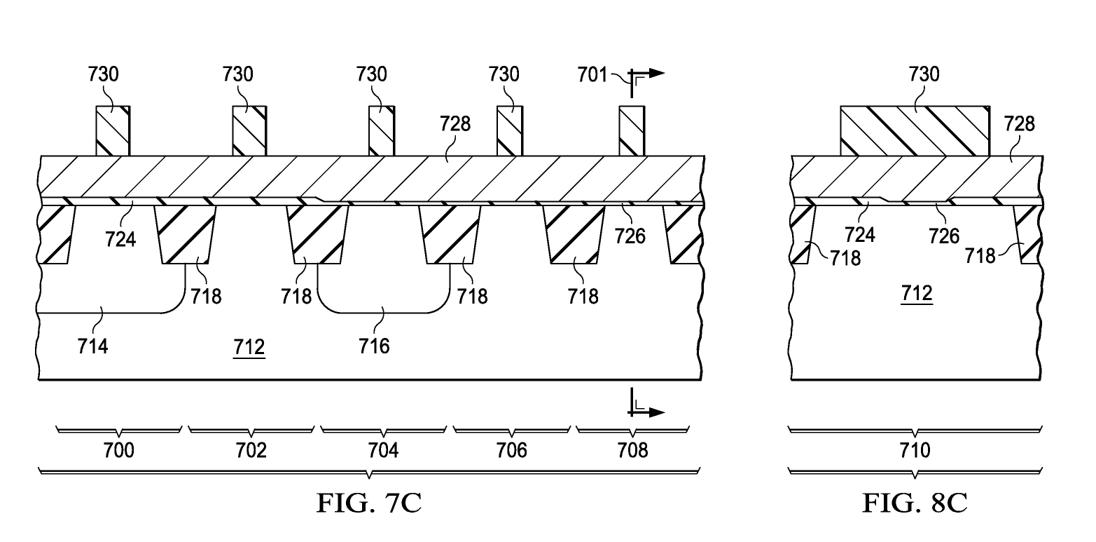

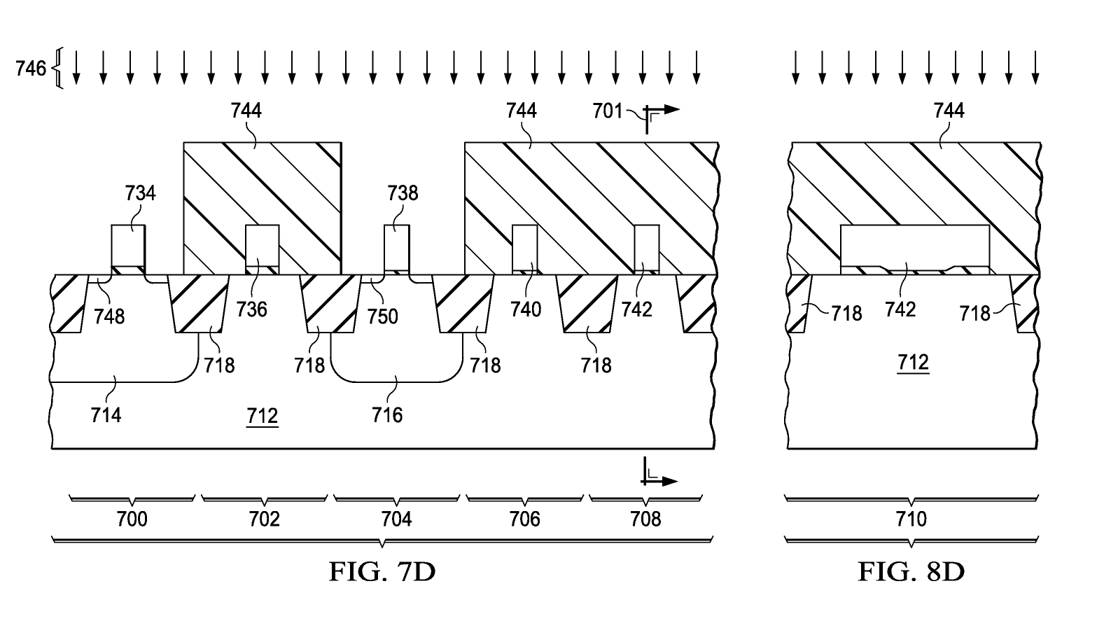

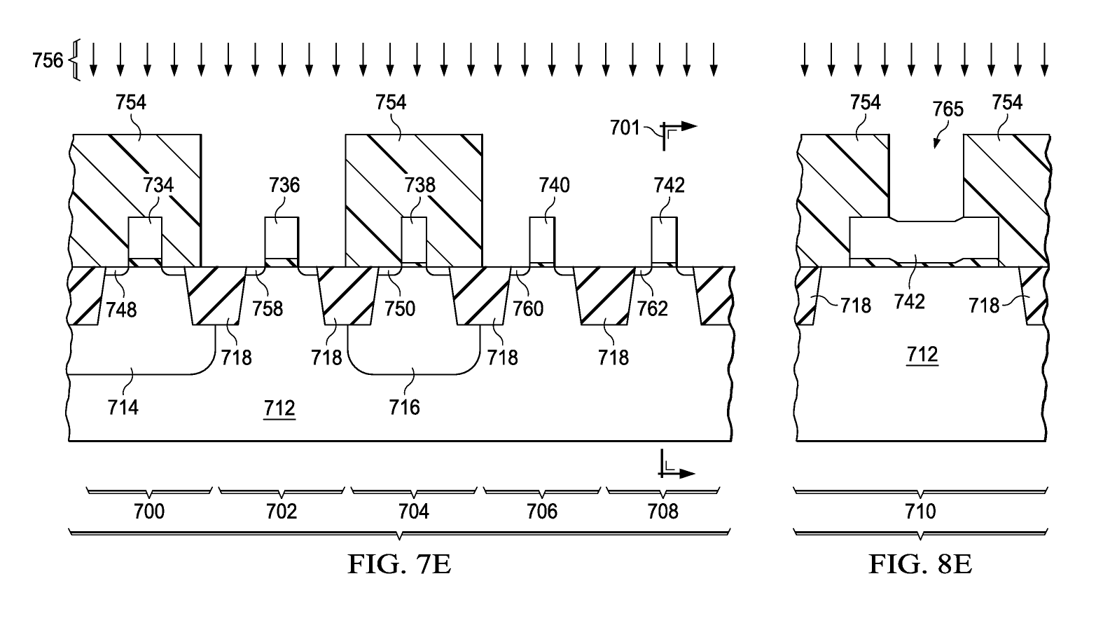

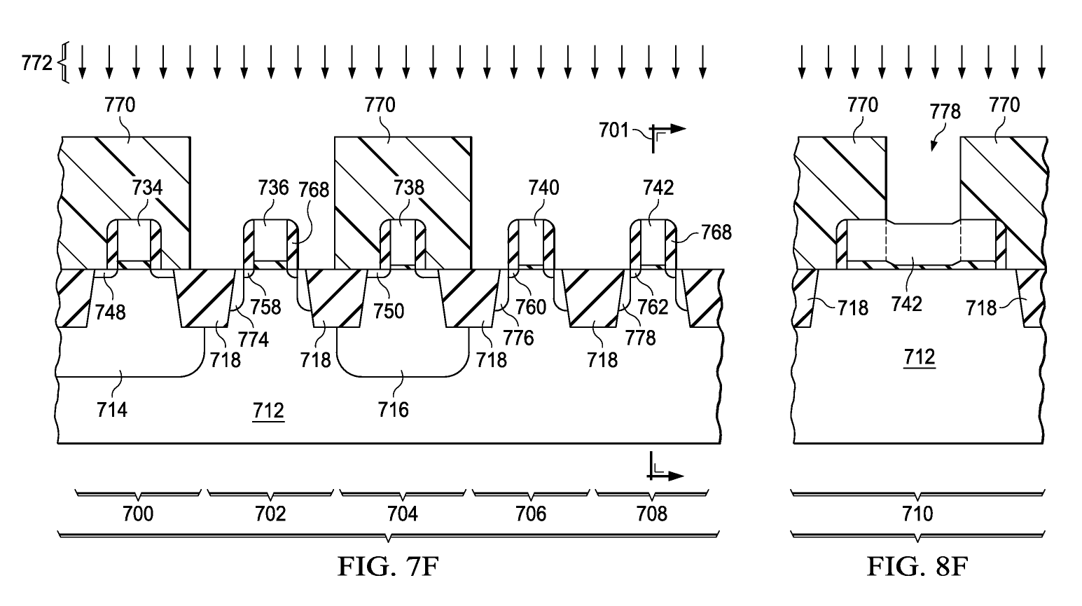

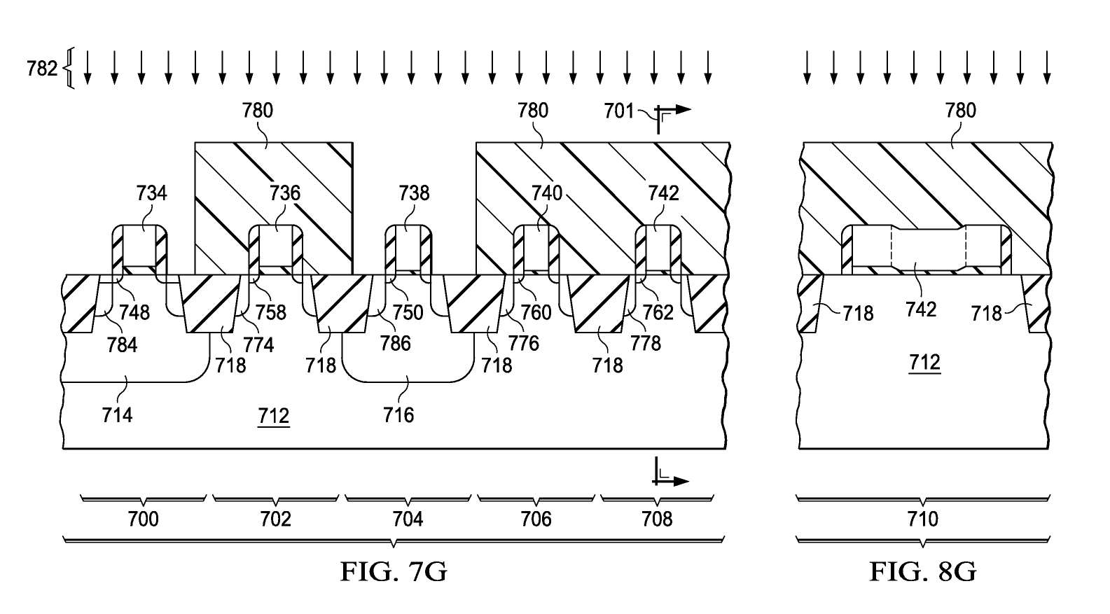

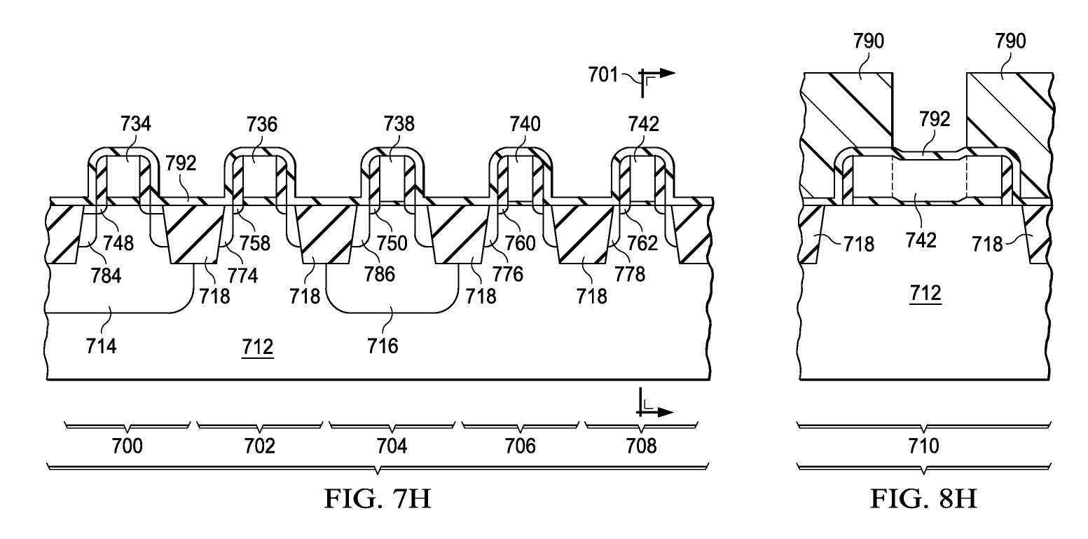

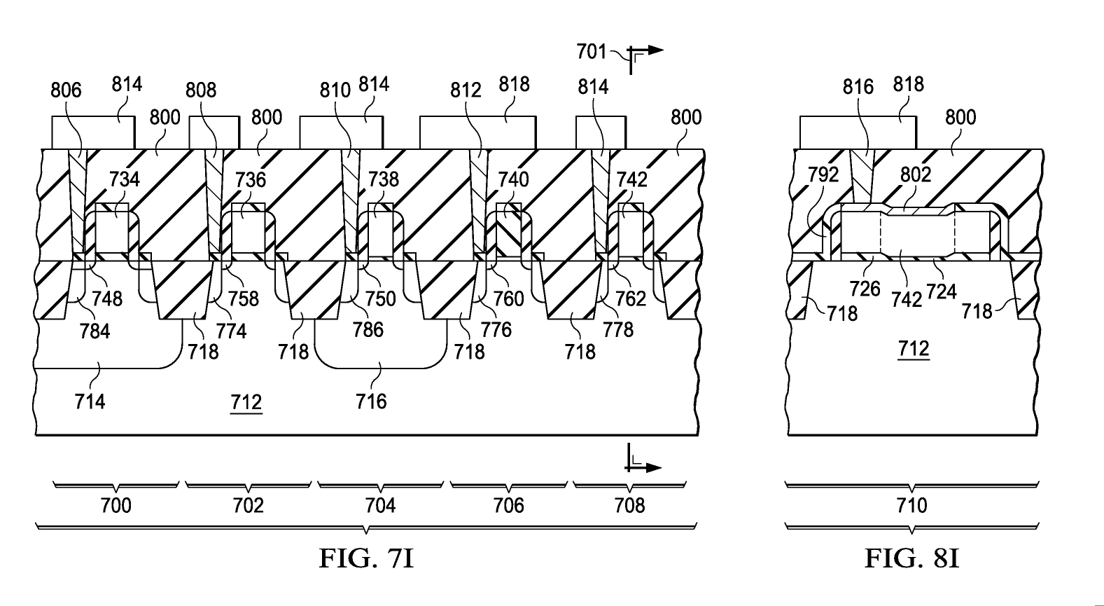

The major steps in an integrated circuit manufacturing flow that builds both high voltage and low voltage transistors are illustrated in the cross sections in FIGS. 7A-7I and cross sections in FIGS. 8A-8I. The cross sections in FIGS. 8A-8I are along cut line 701 in FIGS. 7A-7I. An embodiment radiation hard NMOS transistor is also formed using the integrated circuit manufacturing flow with no added manufacturing cost.

FIG. 7I is a cross section is through a portion of the integrated circuit wafer perpendicular through the transistor gates (gate 734 of an I/O p-channel metal-oxide-semiconductor (PMOS) transistor formed in region 700, gate 736 of an I/O NMOS transistor formed in region 702, gate 738 of a logic PMOS transistor formed in region 704, gate 740 of a logic NMOS transistor formed in region 706, and gate 742 of an embodiment radiation hard NMOS transistor formed in region 708). The cross section 710 in FIG. 8I is parallel through the gate 742 of the embodiment radiation hard NMOS transistor along cut line 701 in FIG. 7I.

As shown in the cross section in FIG. 8I parallel through the gate 742 of the embodiment radiation hard transistor in region 710, the portion of the gate over the channel of the radiation hard transistor is on a thin gate dielectric 724 and the remaining portion of the gate 724 over active that is not the channel is on a thick gate dielectric 726. The gate 742 is formed over active only. The gate does not cross an active 712/isolation 718 boundary.

Referring to FIG. 7A, the integrated circuit wafer is processed through shallow trench isolation (STI) 718. The substrate wafer 712 is p-type. A first nwell 714 is formed in the p-type substrate where the high voltage, I/O PMOS transistor 700 is to be formed. A second nwell 716 is formed in the p-type substrate region 704 where the low voltage, logic PMOS transistor is to be formed. In this split gate (two gate dielectric thickness) manufacturing flow the I/O gate dielectric 720 is partially grown on the wafer. A split gate dielectric photo resist pattern 722 is formed on the wafer exposing the active areas in regions 704 and 706 where the logic transistors are to be formed and in region 708 where the embodiment radiation hard transistor is to be formed. As shown in the cross section in FIG. 8A parallel through the gate of the embodiment radiation hard transistor, (along cut line 701 in FIG. 7A) only the channel area 725 of the embodiment radiation hard transistor is exposed. This pattern 722 permits the partially grown I/O transistor gate dielectric 720 to etched from the low voltage, logic transistor regions, 704 and 706, and etched from the channel region 725 of the embodiment radiation hard transistor.

FIG. 7B shows the cross section of the integrated circuit wafer after the partially grown I/O (high voltage) oxide 724 has been etched from the low voltage transistor regions 704 and 706 and from the channel region of the embodiment rad hard transistor 728 and the logic gate (low voltage) gate dielectric 726 is grown. During growth of the logic gate dielectric 726, the thickness 724 of partially grown I/O transistor dielectric in the I/O transistor regions 700 and 702 and the non-channel regions of the embodiment radiation hard transistor (FIG. 8B) is increased. In an example embodiment 3.3 volt radiation hard transistor flow the high voltage gate dielectric may be in the range of 185 nm to 215 nm and the low voltage gate dielectric may be in the range of 78 nm to 88 nm. In an example embodiment 3.3 volt radiation hard transistor flow the high voltage gate dielectric is about 200 nm and the low voltage gate dielectric is about 83 nm.

Referring now to FIG. 7C, gate material 728 is deposited on the gate dielectrics 724 and 726 and a transistor gate photo resist pattern 730 is formed on the gate material 728. Gate resist geometries are formed where the gates of the transistors are to be etched. The gate material may be undoped or doped polysilicon.

As is illustrated in FIG. 7D, the gate 734 of the PMOS I/O transistor, the gate 736 of the NMOS I/O transistor, the gate 738 of the logic PMOS transistor, the gate 740 of the logic NMOS transistor, and the gate 742 of the embodiment radiation hard NMOS transistor are etched. A PMOS transistor source and drain extension photo resist pattern 744 is formed on the integrated circuit wafer with openings over the I/O 700 and logic 704 PMOS transistor regions. A p-type dopant 746 such as boron or BF₂ is implanted to form source and drain extensions 748 and 750 on the PMOS I/O transistor and on the PMOS logic transistor. N-type dopant may also be implanted at an angle to form halos or pockets on the PMOS transistors in regions 700 and 704.

In FIG. 7E, an NMOS transistor source and drain extension photo resist pattern 754 is formed on the integrated circuit wafer with openings over the I/O 702 and logic 708 NMOS transistor regions.

An opening is also formed over the radiation hard NMOS transistor region 708 and 710 (FIG. 8E). The opening 765 in the resist over the gate of the radiation hard NMOS transistor 710 allows the extension implant 756 into the source and drain regions 762 adjacent to the radiation hard transistor channel and blocks the implant from active regions outside the source and drain regions of the radiation hard transistor. An n-type dopant 756 such as phosphorus and arsenic is implanted to form source and drain extensions 758 and 760 on the NMOS I/O transistor and on the NMOS logic transistor in regions 702 and 706. Source and drain extensions 762 are also formed on the embodiment radiation hard NMOS transistor 708 and 710 (FIG. 8E). P-type dopant may also be implanted at an angle to form halos or pockets on the NMOS transistors in regions 702, 706, and 708.

Referring now to FIG. 7F, sidewalls 768 are formed on the vertical surfaces of the transistor gates 734, 736, 738, 740, and 742. An NMOS source and drain photo resist pattern 770 is formed on the integrated circuit wafer and n-type dopants 772 such as phosphorus and arsenic are implanted to form deep source and drain diffusions 774 on the NMOS I/O transistor in region 702, deep source and drain diffusions 776 on the NMOS logic transistor 706 in region 706, and deep source and drain diffusions 778 on the embodiment radiation hard NMOS transistor in regions 708 and 710 (FIG. 8F). The opening 778 in the resist over the gate of the radiation hard NMOS transistor 708 allows the source and drain implant 772 into the source and drain regions 778 that are adjacent to the channel of the embodiment radiation hard NMOS transistor in regions 708 and 710 (FIG. 8F).

A PMOS source and drain photo resist pattern 780 is formed on the integrated circuit wafer in FIG. 7G. P-type dopants 782 such as boron and BF2 are implanted to form deep source and drain diffusions 784 on the PMOS I/O (high voltage) transistor in region 700 and deep source and drain diffusions 786 on the PMOS logic (low voltage) transistor in region 704.

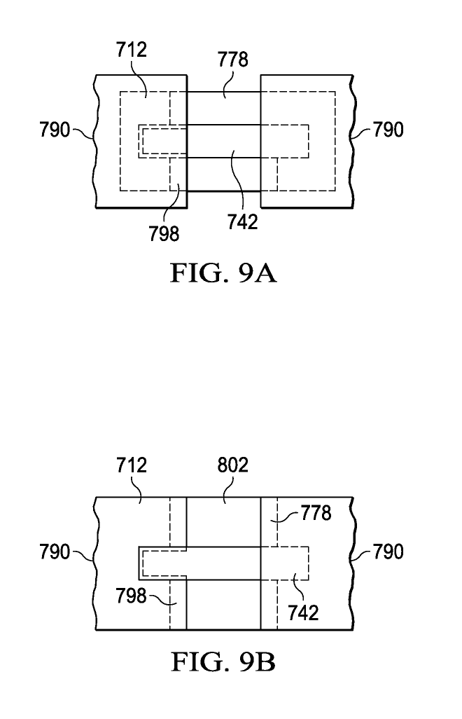

A silicide block dielectric layer 792 is then deposited on the integrated circuit wafer as shown in FIG. 7H and 8H and a silicide block photo resist pattern 790 is formed on the silicide block dielectric layer 792 with geometries over regions where silicide formation is to be blocked (FIG. 8H). The silicide block pattern covers the pn-junctions formed at the boundary 798 (plan view in FIG. 9A) between the embodiment radiation hard transistor source and drain diffusions 778 and the active 712 to prevent the silicide from shorting the source and drain diodes 778 to substrate.

FIGS. 7I and 8I show the integrated circuit after the silicide block dielectric 792 layer is etched and silicide 802 is formed on the exposed source and drain diffusions and silicide 802 is formed on transistor gates. As is illustrated in the plan view in FIG. 9B silicide is blocked from forming on the source and drain pn-junctions 798 to prevent the source and drain junctions from shorting to the substrate 712. Premetal dielectric layer 800 is deposited on the integrated circuit wafer and planarized using CMP. Contact plugs 806, 808, 810, 812, and 814 are formed to electrically connect the transistor deep source and drain diffusions, 774, 776, 778, 784, and 786 to the first level of interconnect 818. Contacts 816 are also formed to connect the transistor gates 734, 736, 738, 740, and 742 to the first level of interconnect 814.

Additional levels of dielectric and interconnect may be formed on the integrated circuit wafer to complete the integrated circuit.

Those skilled in the art to which this invention relates will appreciate that many other embodiments and variations are possible within the scope of the claimed invention. For example although the radiation hard transistor embodiments are illustrated with an embodiment NMOS radiation hard transistor, the radiation hard transistor embodiments may also be illustrated with an embodiment PMOS radiation hard transistor as is evident to those skilled in the art.

What is claimed is:

1. An integrated circuit, comprising:
a radiation hard MOS transistor, the radiation hard transistor further comprising:
an active region in a substrate of the integrated circuit wherein the active region is surrounded by isolation dielectric;
a radiation hard transistor gate on the active region wherein the radiation hard transistor gate does not cross a boundary between the active region and the isolation dielectric;
a first portion of the radiation hard transistor gate over a first gate dielectric wherein the first gate dielectric overlies active adjacent to a channel of the radiation hard transistor;
a second portion of the radiation hard transistor gate over a second gate dielectric and wherein the second gate dielectric overlies the channel;
a source diffusion and a drain diffusion that is implanted self-aligned to the second portion; and
silicide formed on a portion of the source diffusion and on a portion of the drain diffusion wherein the silicide does not short pn-junctions formed between the source diffusion and the drain diffusions and the substrate.

2. The integrated circuit of claim 1, wherein the radiation hard MOS transistor is a radiation hard NMOS transistor.

3. The integrated circuit of claim 1, wherein the radiation hard MOS transistor is a radiation hard PMOS transistor.

4. The integrated circuit of claim 1, wherein the radiation hard transistor is a high voltage radiation hard transistor and wherein the first gate dielectric and the second gate dielectric are the same gate dielectric.

5. The integrated circuit of claim 1, wherein the radiation hard transistor is a low voltage radiation hard transistor and wherein the first gate dielectric is at least twice the thickness of the second gate dielectric.

6. The integrated circuit of claim 1 further comprising a low voltage MOS transistor formed on the second gate dielectric and a high voltage MOS transistor formed on the first gate dielectric and wherein the first gate dielectric is at least twice the thickness of the second gate dielectric.

7. An integrated circuit with a radiation hard dual MOS transistor comprising:
an active region in a substrate of the integrated circuit wherein the active region is surrounded by isolation dielectric;
radiation hard transistor dual gate over the active region wherein the dual gate does not cross a boundary between the active region and the isolation dielectric;
an opening within the radiation hard transistor dual gate between a first gate and a second gate which surrounds a common drain of the radiation hard dual transistor;
a first portion of the radiation hard transistor dual gate on a first dielectric outside a first channel under the first gate and outside a second channel under the second gate;
a second gate dielectric on the first channel and the second gate dielectric on the second channel;
a first source diffusion adjacent to the first channel;
a second source diffusion adjacent to the second channel;
a common drain diffusion between the first channel and the second channel; and
silicide formed on a portion of the first and the second source diffusions and on the common drain diffusion wherein the silicide does not short pn-junctions formed between the first and second source diffusions and the substrate.

8. The integrated circuit of claim 7, wherein the radiation hard dual transistor is a high voltage radiation hard dual transistor and wherein the first gate dielectric and the second gate dielectric are the same gate dielectric.

9. The integrated circuit of claim 7, wherein the radiation hard dual transistor is a low voltage radiation hard dual transistor and wherein the first gate dielectric is at least twice the thickness of the second gate dielectric.

10. The integrated circuit of claim 7 further including a low voltage MOS transistor formed on the second gate dielectric and a high voltage MOS transistor formed on the first gate dielectric and wherein the first gate dielectric is at least twice the thickness of the second gate dielectric.

11. The integrated circuit of claim 7 further including rounding inside corners on the opening which surrounds the common drain and increasing an area of the common drain.

12. The integrated circuit of claim 11, wherein silicide is blocked from the increased area.

13. A process of forming an integrated circuit, comprising the steps:
forming a radiation hard transistor active area in the substrate of the integrated circuit wherein the radiation hard transistor active area is surrounded by isolation dielectric;
growing a first gate dielectric on the radiation hard transistor active area;
depositing gate material on the first gate dielectric;
forming a gate photo resist pattern on the gate material with a radiation hard transistor gate pattern;
etching the gate material to form a radiation hard transistor gate on the radiation hard transistor active area wherein the radiation hard transistor gate does not cross a boundary between the radiation hard transistor active and the isolation dielectric, wherein a first portion of the radiation hard transistor gate overlies a channel of the radiation hard transistor, and wherein a second portion of the radiation hard transistor gate overlies the active area outside of the channel;
forming sidewalls on the radiation hard transistor gate;
forming a source and drain implant photo resist pattern on the substrate wafer;
implanting the source and drain dopants into source and drain regions of the radiation hard transistor wherein the source and drain regions of the radiation hard transistor are implanted self-aligned to the sidewalls and adjacent to the channel under the first portion of the radiation hard transistor gate;
depositing a silicide blocking layer on the integrated circuit;
forming a silicide block photo pattern on the integrated circuit wherein the silicide block photo pattern covers a first portion of the source and drain regions that includes the pn-junction formed between the source and drains and the substrate and wherein the silicide block photo pattern has openings over a second portion of the source and drain regions which are surrounded by the first portion;
etching the silicide blocking layer; and
forming silicide on the second portion of the source and drain regions.

14. The process of claim 13, wherein the radiation hard transistor is a high voltage radiation hard transistor and wherein the first gate dielectric and the second gate dielectric are the same gate dielectric.

15. The process of claim 13 further including:
prior to the step of depositing the gate material, forming a gate dielectric pattern on the first gate dielectric with an opening over the channel of the radiation hard transistor;
etching the first gate dielectric from the opening;
removing the gate dielectric pattern; and
growing a second gate dielectric on the channel wherein the first gate dielectric is at least twice as thick as the second gate dielectric.

16. The process of claim 15 further including forming a high voltage transistor over the first gate dielectric and forming a low voltage transistor over the second gate dielectric.

17. A process claim 13 further comprising the steps:
wherein the radiation hard transistor gate pattern is a radiation hard transistor dual gate pattern;
during the step of etching the gate material, forming a radiation hard dual transistor gate with a first gate of a first radiation hard transistor and with a second gate of a second radiation hard transistor and wherein an opening in the gate material is between the first and second gates and wherein a common drain is formed in the opening;
implanting the source and drain dopants into a first source of the first radiation hard transistor;
implanting the source and drain dopants into a second source of the second radiation hard transistor; and
implanting the source and drain dopants into the common drain shared by the first radiation hard transistor and the second radiation hard transistor.

18. The process of claim 17 further comprising forming rounded corners in the opening in the radiation hard dual transistor gate and wherein an area of the common drain is increased.

19. The process of claim 18 further comprising blocking silicide formation from a region where the area of the common drain is increased.
